(19) United States
(12) Patent Application Publication
(10) Pub. No.: US 2013/0312460 A1
(43) Pub. Date: Nov. 28, 2013

(54) MANUFACTURING METHOD OF SINGLE CRYSTAL SUBSTRATE AND MANUFACTURING METHOD OF INTERNAL MODIFIED LAYER-FORMING SINGLE CRYSTAL MEMBER

(71) Applicants: Yosuke Kunishi, Gyoda-shi (JP); Hideki Suzuki, Katsushika-ku (JP); Rika Matsuo, Kawagoe-shi (JP); Junichi Ikeno, Saitama-shi (JP)

(72) Inventors: Yosuke Kunishi, Gyoda-shi (JP); Hideki Suzuki, Katsushika-ku (JP); Rika Matsuo, Kawagoe-shi (JP); Junichi Ikeno, Saitama-shi (JP)

(73) Assignees: NATIONAL UNIVERSITY CORPORATION SAITAMA UNIVERSITY, Saitama-shi, Saitama (JP); SHIN-ETSU POLYMER CO., LTD., Tokyo (JP)

(21) Appl. No.: 13/984,047

(22) PCT Filed: Feb. 10, 2011
(86) PCT No.: PCT/JP2011/052949

§ 371 Date: Aug. 7, 2013

(51) Int. Cl. C30B 30/00

(52) U.S. Cl. CPC C30B 30/00
USPC 65/112

(57) ABSTRACT

It is an object of the present invention to provide a manufacturing method of a single crystal substrate and to provide an internal modified layer-forming single crystal member, each of which is capable of easily manufacturing a relatively large and thin single crystal substrate. The manufacturing method of a single crystal substrate includes: the step of arranging a condensing lens (15), which emits laser beams (B) and corrects aberration caused by a refractive index of a single crystal member (10), contactlessly on the single crystal member (10); the step of irradiating the laser beams onto a surface (10t) of the single crystal member (10), and condensing the laser beams into an inside of the single crystal member; the step of moving the condensing lens (15) and the single crystal member (10) relatively to each other, and forming a two-dimensional modified layer (12) in the inside of the single crystal member (10); and the step of exfoliating a single crystal layer, which is formed by being divided by the modified layer (12), from the modified layer (12), thereby forming a single crystal substrate.

### TECHNICAL FIELD

The present invention relates to a manufacturing method of a single crystal substrate and a manufacturing method of an internal modified layer-forming single crystal member, and particularly, relates to a manufacturing method of a single crystal substrate and a manufacturing method of an internal modified layer-forming single crystal member, each of which cuts out a single crystal substrate thinly and stably.

### BACKGROUND ART

Heretofore, in the case of manufacturing a semiconductor wafer represented by a single crystal silicon (Si) wafer, such a procedure as below has been adopted. A columnar ingot, which is formed by coagulating silicon melt molten in a quartz crucible, is cut into a block with an appropriate length, a peripheral edge portion thereof is ground so that the ingot cut into the block can have a target diameter, thereafter, the ingot concerned is sliced into a wafer-shaped piece by a wire saw, whereby the semiconductor wafer is manufactured.

The semiconductor wafer thus manufactured is sequentially subjected to a variety of treatment such as formation of a circuit pattern in a pre-process, and is then fed to a post-process, and in this post-process, a back surface thereof is subjected to back grinding, and the semiconductor wafer concerned is thinned, whereby a thickness thereof is adjusted from approximately 750 μm to 100 μm or less, for example, approximately 75 μm and 50 μm.

The conventional semiconductor wafer is manufactured in such a manner as described above. The ingot is cut by the wire saw, and in addition, in the event where the ingot is cut thereby, a cutting margin thicker than the wire saw is necessary. Accordingly, there are problems that it is extremely difficult to manufacture a semiconductor wafer as thin as a thickness of 0.1 mm or less, and that a yield of the product is not enhanced, either.

Moreover, in recent years, silicon carbide (SiC), which has high thermal conductivity as well as large hardness, has attracted attention as a next-generation semiconductor; however, in the case of SiC, since hardness thereof is larger than that of Si, an ingot thereof cannot be sliced with ease by the wire saw, and it is not easy to thin a substrate as a sliced product by the back grinding, either.

Meanwhile, there are disclosed a substrate manufacturing method and a substrate manufacturing apparatus, in which a condensing point of laser beams is set into an inside of an ingot by a condensing lens, and the ingot is relatively scanned by the laser beams concerned, whereby a planar modified layer, which is formed by multiphoton absorption, is formed in the inside of the ingot, and a part of the ingot is exfoliated as a substrate while taking this reformed layer as an exfoliation surface.

For example, Patent Document 1 discloses a technology for forming the modified layer in an inside of a silicon ingot by using the multiphoton absorption of the laser beams, and then exfoliating a wafer from the silicon ingot by using an electrostatic chuck.

Moreover, Patent Document 2 discloses a technology for attaching a glass plate onto an objective lens with a numerical aperture (NA) of 0.8, irradiating the laser beams toward a silicon wafer for a solar cell, thereby forming the modified layer in an inside of the silicon wafer, and fixing this modified layer to an acrylic resin plate by an instantaneous adhesive, followed by exfoliation thereof.

Furthermore, Patent Document 3 discloses, particularly in paragraphs 0003 to 0005, 0057 and 0058 thereof, a technology for condensing the laser beams into an inside of a silicon wafer, causing the multiphoton absorption therein, and thereby forming micro-cavities therein, followed by dicing.

However, in accordance with the technology of Patent Document 1, it is not easy to uniformly exfoliate a substrate (silicon substrate) with a large area.

Moreover, in accordance with the technology of Patent Document 2, it is necessary to fix the wafer to the acrylic resin plate by a cyanoacrylate-based strong adhesive in order to exfoliate the wafer, and it is not easy to separate the exfoliated wafer and the acrylic resin plate from each other. Furthermore, when a modified region is formed in the inside of the silicon by a lens with the NA of 0.5 to 0.8, then a thickness of the modified layer becomes 100 μm or more, which is a thickness larger than the necessary thickness, and accordingly, a large loss occurs. Here, it is conceived to reduce the thickness of the reformed layer by reducing the NA of the objective lens that condenses the laser beams; however, a spot diameter of the laser beams on a surface of the substrate becomes undesirably small. Therefore, when the modified layer is attempted to be formed at a shallow depth, there occurs another problem that up to the surface of the substrate is undesirably processed.

Furthermore, the technology of Patent Document 3 is a technology regarding the dicing of cutting and dividing the silicon wafer into individual chips, and it is not easy to apply this technology to manufacturing of such a thin plate-like wafer from the single crystal ingot of the silicon or the like.

### CITATION LIST

### Patent Document

[Patent Document 1] JP 2005-277136 A

[Patent Document 2] JP 2010-188385 A

[Patent Document 3] JP 2005-57257 A

### SUMMARY OF INVENTION

### Technical Problem

In consideration of the foregoing problems, it is an object of the present invention to provide a manufacturing method of a single crystal substrate and a manufacturing method of an internal modified layer-forming single crystal member, each of which is capable of easily manufacturing a relatively large and thin single crystal substrate.

### SOLUTION TO PROBLEM

In accordance with an aspect of the present invention for achieving the foregoing object, there is provided a manufacturing method of a single crystal substrate, including the steps of: arranging a laser condenser contactlessly on a single crystal member, the laser condenser emitting laser beams and correcting aberration caused by a refractive index of the single crystal member; by the laser condenser, irradiating the laser beams onto a surface of the single crystal member, and condensing the laser beams into an inside of the single crystal member; moving the laser condenser and the single crystal member relatively to each other, and forming a two-dimensional modified layer in the inside of the single crystal member; and exfoliating a single crystal layer from the modified layer, the single crystal layer being formed by being divided by the modified layer, thereby forming a single crystal substrate.

In accordance with another aspect of the present invention, there is provided a manufacturing method of an internal modified layer-forming single crystal member for forming a modified layer in an inside of a single crystal member by irradiating laser beams onto the single crystal member from a surface of the single crystal member and condensing the laser beams in an inside of the single crystal member, and for exfoliating the single crystal substrate from the modified layer, the manufacturing method including the steps of: arranging a laser condenser contactlessly on the single crystal member, the laser condenser emitting the laser beams and correcting aberration caused by a refractive index of the single crystal member; by the laser condenser, irradiating the laser beams onto the surface of the single crystal member, and condensing the laser beams into the inside of the single crystal member; and moving the laser condenser and the single crystal member relatively to each other, and forming a two-dimensional modified layer in the inside of the single crystal member.

### ADVANTAGEOUS EFFECTS OF INVENTION

In accordance with the present invention, there can be provided the manufacturing method of a single crystal substrate and the manufacturing method of an internal modified layer-forming single crystal member, each of which is capable of easily manufacturing the relatively large and thin single crystal substrate.

### BRIEF DESCRIPTION OF DRAWINGS

FIG. 1 is a schematic bird's-eye view explaining a single crystal substrate manufacturing method according to a first embodiment.

FIG. 2 is a schematic bird's eye view explaining the single crystal substrate manufacturing method according to the first embodiment.

FIG. 3 is a schematic perspective cross-sectional view explaining the single crystal substrate manufacturing method according to the first embodiment and an internal modified layer-forming single crystal member according thereto.

FIG. 4 is a schematic cross-sectional view showing that cracks are formed in an inside of the single crystal member by irradiation of laser beams in the first embodiment.

FIG. 5 is a schematic perspective cross-sectional view showing that a modified layer is exposed to a sidewall of the internal modified layer-forming single crystal member in the first embodiment.

FIG. 6 is a schematic cross-sectional view explaining that, in the first embodiment, metal-made substrates are adhered onto upper and lower surfaces of the internal modified layer-forming single crystal member, and a single crystal layer is exfoliated from the reformed layer.

FIG. 7 is a schematic cross-sectional view explaining that, in the first embodiment, the metal-made substrates are adhered onto the upper and lower surfaces of the internal modified layer-forming single crystal member, and the single crystal layer is exfoliated from the reformed layer.

FIG. 8 is a schematic cross-sectional view explaining a modification example of the first embodiment.

FIG. 9 is a schematic cross-sectional view explaining the modification example of the first embodiment.

FIG. 10 is a schematic perspective cross-sectional view explaining the modification example of the first embodiment.

FIG. 11 is an optical microscope photograph showing an example of the exfoliation surface of the single crystal layer in the first embodiment.

FIG. 12 is an optical microscope photograph of a cleavage plane of a silicon wafer in Example 1 of Test example 1.

FIG. 13 is an optical microscope photograph of a cleavage plane of a silicon wafer in Example 2 of Test example 1.

FIG. 14 is a graph showing a relationship between an irregularity dimension and surface roughness of the exfoliation surface of the single crystal substrate in Test example 2.

FIG. 15 is an optical microscope photograph and spectrum chart of a cross section of an internal modified layer-forming single crystal member in Example 4 of Test example 3.

FIG. 16 is a schematic bird's eye view explaining that laser beams are irradiated onto a silicon wafer in Comparative example of Test example 3.

FIG. 17 is a schematic bird's eye view of a single crystal member inside processing apparatus for use in an event of explaining a single crystal substrate manufacturing method according to a second embodiment and an internal modified layer-forming single crystal member according thereto.

### DESCRIPTION OF EMBODIMENTS

A description is made below of embodiments of the present invention with reference to the drawings. In the following description referring to the drawings, the same or similar reference numerals are assigned to the same or similar portions. It should be noted that the drawings are schematic, and that a relationship between a thickness and a flat dimension, a thickness ratio of the respective layers, and the like are different from actual ones. Hence, specific thicknesses and dimensions should be determined in consideration of the following description. Moreover, as a matter of course, portions different in mutual dimensional relationship and ratio are also included among the drawings.

Moreover, the embodiments shown below illustrate apparatuses and methods for embodying technical idea of this invention, and the embodiments of this invention do not specify materials, shapes, structures, arrangements and the like of constituent components to the following ones. The embodiments of this invention can be added with a variety of alterations within the scope of claims.

Note that, in a second embodiment, the same referent numerals are assigned to similar constituent elements to those already described, and a description thereof is omitted.

### First Embodiment

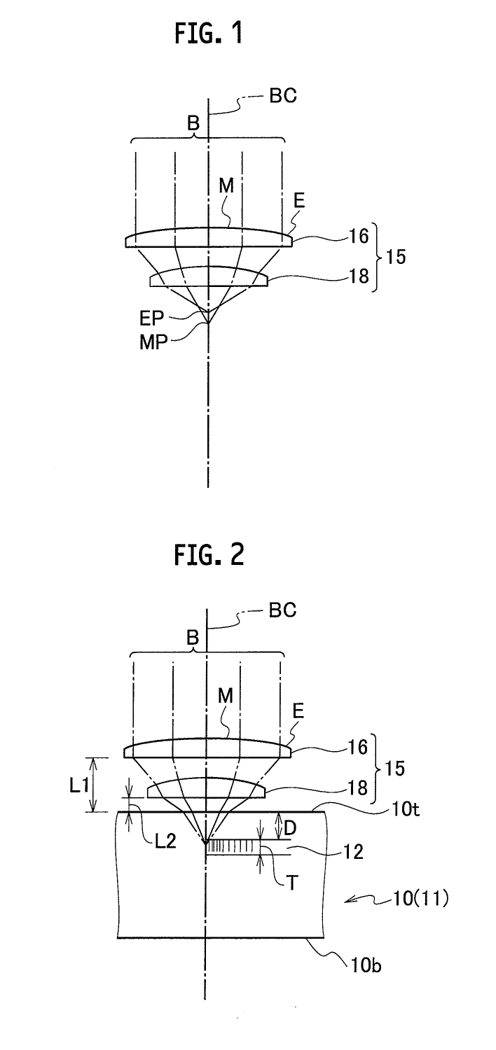

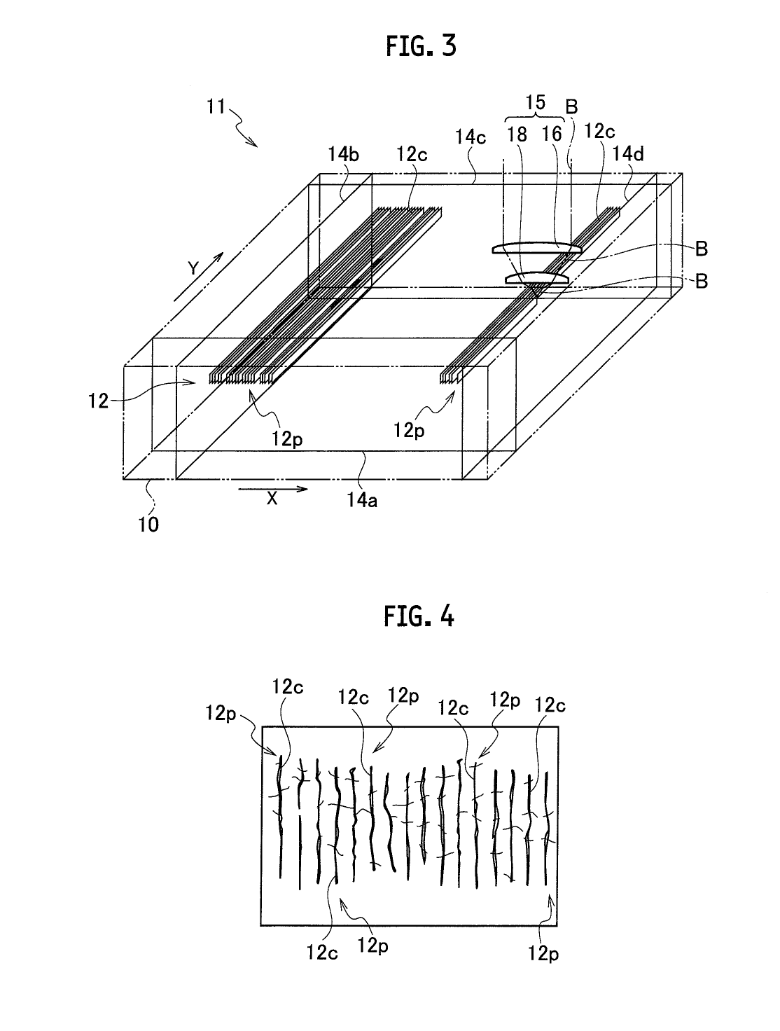

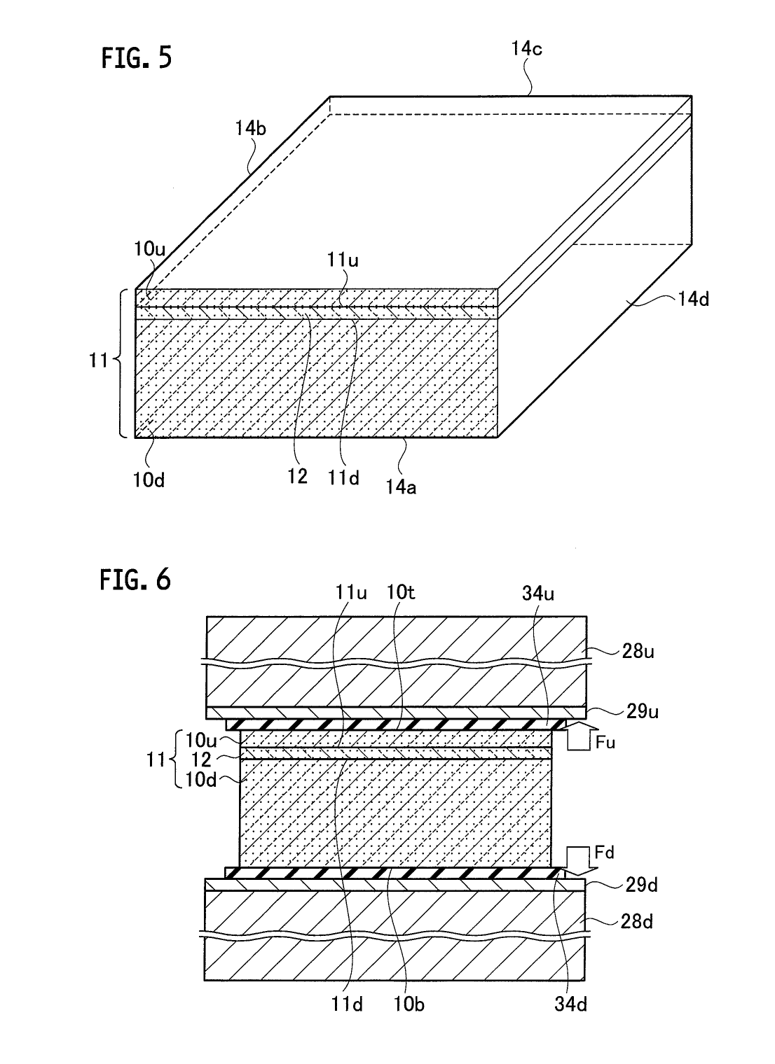

First, a description is made of a first embodiment. FIG. 1 is a schematic bird's-eye view explaining that laser beams are condensed in air by a laser condenser in this embodiment, and FIG. 2 is a schematic bird's eye view explaining that the laser beams are condensed into an inside of a single crystal member by the laser condenser in this embodiment. FIG. 3 shows a schematic cross-sectional structure explaining a single crystal substrate manufacturing method according to this embodiment and an internal modified layer-forming single crystal member 11 according thereto. FIG. 4 is a schematic cross-sectional view showing that cracks 12c are formed in the inside of the single crystal member by irradiation of the laser beams. FIG. 5 is a schematic perspective cross-sectional view showing that a modified layer 12 formed by the condensation of the laser beams is exposed to a sidewall of the internal modified layer-foaming single crystal member 11.

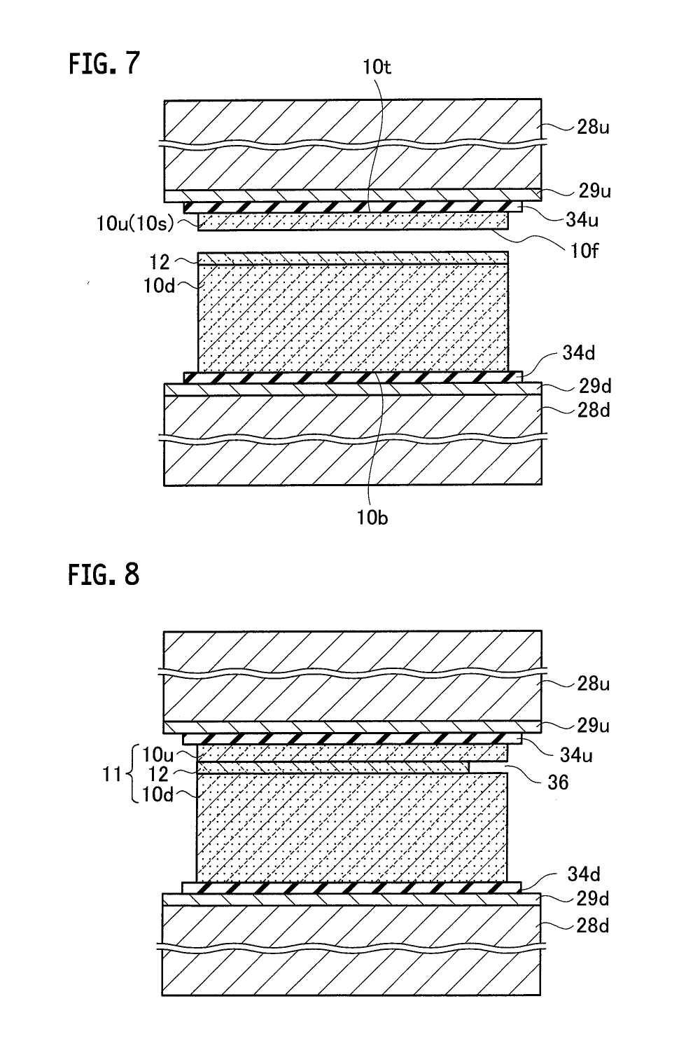

The single crystal substrate manufacturing method according to this embodiment includes: a step of arranging a condensing lens 15 as the laser condenser (laser condensing unit) contactlessly on a single crystal member 10; a step of irradiating laser beams B onto a surface of the single crystal member 10 and condensing the laser beams B into an inside of the single crystal member 10; a step of moving the condensing lens 15 and the single crystal member 10 relatively to each other, and forming a two-dimensional modified layer 12 in the inside of the single crystal member 10; and a step of exfoliating a single crystal layer 10u, which is formed by being divided by the modified layer 12, from an interface thereof with the modified layer 12, thereby forming a single crystal substrate 10s as shown in FIG. 7. Here, FIG. 7 is a schematic cross-sectional view explaining that the single crystal layer 10u is exfoliated from the modified layer 12. Note that, in the following, the description is made on the premise that the single crystal layer 10u is exfoliated from the interface with the modified layer 12; however, the present invention is not limited to this case where the single crystal layer 10u is exfoliated from the interface, and such exfoliation may be allowed to occur in the modified layer 12.

The condensing lens 15 is configured to correct aberration caused by a refractive index of the single crystal member 10. Specifically, as shown in FIG. 1, in this embodiment, the condensing lens 15 is configured to make correction so that, in the event where the laser beams are condensed in the air, the laser beams which have reached an outer circumferential portion E of the condensing lens 15 can be condensed on a condensing lens side more than the laser beams which have reached a center portion M of the condensing lens 15 are. That is to say, the condensing lens 15 is configured to make correction so that, in the event where the laser beams are condensed, a condensing point EP of the laser beams which have reached the outer circumferential portion E of the condensing lens 15 can be located at a position closer to the condensing lens 15 in comparison with a condensing point MP of the laser beams which have reached the center portion M of the condensing lens 15.

A description of the above is made in detail. The condensing lens 15 is composed of a first lens 16 that condenses the laser beams in the air, and a second lens 18 arranged between this first lens 16 and the single crystal member 10. Each of the first lens 16 and the second lens 18 is set to be a lens that can condense the laser beams into a conical shape. Then, a configuration is adopted, in which a depth (interval) D to the modified layer 12 from a surface 10t (surface on an irradiated side) of the single crystal member 10 on a side onto which the laser beams B are irradiated is adjusted mainly by a distance L1 between the first lens 16 and this surface 10t. Moreover, a configuration in which a thickness T of the modified layer 12 is adjusted mainly by a distance L2 between the second lens 18 and this surface 10t is adopted. Hence, the aberration correction in the air is performed mainly by the first lens 16, and the aberration correction in the single crystal member 10 is performed mainly by the second lens 18. In this embodiment, focal lengths of the first lens 16 and the second lens 18 and the above-described distances L1 and L2 are preset so that the modified layer 12 with the thickness T of less than 60 μm can be formed at a position with the predetermined depth D from the surface 10t.

As the first lens 16, it is possible to use, as well as spherical or aspherical single lens, a combined lens in order to perform various kinds of the aberration correction and ensure an operation distance, and preferably, an NA of the first lens 16 is 0.3 to 0.7. As the second lens 18, a lens with an NA smaller than that of the first lens 16, which is also a convex glass lens, for example, with a curvature radius of approximately 3 to 5 mm, is preferable from a viewpoint of simple and easy use.

Then, an NA of the condensing lens 15 in the air, which is defined by the laser beams which have reached the outer circumferential portion E of the condensing lens 15 and by the condensing point EP thereof, is set preferably within a range of 0.3 to 0.85, more preferably, within a range of 0.5 to 0.85 from a viewpoint of forming the modified layer 12 in the inside of the single crystal member 10 without damaging the surface 10t of the single crystal member 10 by the irradiation of the laser beams B.

Note that, in the case where it is unnecessary to adjust the thickness of the modified layer 12, it is also possible to arrange only one lens instead of the first lens 16 and the second lens 18. In that case, preferably, a structure that makes it possible to perform the aberration correction in the single crystal member is made in advance.

A size of the single crystal member 10 is not particularly limited; however, preferably, the single crystal member 10 is composed of a thick silicon wafer, for example, with a diameter of Ø 300 mm, and the surface 10t onto which the laser beams B are irradiated is planarized in advance.

The laser beams B are irradiated not onto a circumferential surface of the single crystal member 10 but onto the above-described surface 10t from an irradiation apparatus (not shown) through the condensing lens 15. In the case where the single crystal member 10 is silicon, the laser beams B are composed of pulse laser beams, for example, with a pulse width of 1 μs or less, in which a wavelength of 900 nm or more, preferably, 1000 nm or more is selected. A YAG laser or the like is suitably used.

A form of allowing the laser beams to enter the condensing lens 15 from the above is not particularly limited. There may be adopted: a form, in which a laser oscillator is arranged above the condensing lens 15, and the laser beams are emitted toward the condensing lens 15; or a form, in which a reflection mirror is arranged above the condensing lens 15, and the laser beams are irradiated toward the reflection mirror, and are reflected toward the condensing lens 15 by the reflection mirror.

Desirably, the laser beams B have a wavelength in which light transmittance at a time of being irradiated onto a single crystal substrate with a thickness of 0.625 mm, which serves as the single crystal member 10, is 1 to 80%. For example, in the case of using a silicon single crystal substrate as the single crystal member 10, laser beams with a wavelength of 800 nm or less are absorbed thereto to a large extent, and accordingly, only a surface thereof is processed, and the internal modified layer 12 cannot be formed in the inside of the single crystal member 10. Accordingly, the wavelength of 900 nm or more, preferably, 1000 nm or more is selected. Moreover, light transmittance of a CO₂ laser with a wavelength of 10.64 μm is too high, and accordingly, the CO₂ laser has difficulty processing the single crystal substrate. Therefore, a laser of a YAG fundamental wave, or the like is suitably used.

A reason why 900 nm or more is preferable as the wavelength of the laser beams B is that, if the wavelength is 900 nm or more, then the transmittance of the laser beams B through the single crystal substrate made of silicon is enhanced, and the modified layer 12 can be surely formed in the inside of the single crystal substrate. The laser beams B are irradiated onto a peripheral edge portion of the surface of the single crystal substrate, or are irradiated in a direction of the peripheral edge portion from the center portion of the surface of the single crystal substrate.

(Formation process of modified layer)

As a process of moving the condensing lens 15 and the single crystal member 10 relatively to each other and forming the modified layer 12 in the inside of the single crystal member 10, for example, the single crystal member 10 is mounted on an XY stage (not shown), and this single crystal member 10 is held by a vacuum chuck, an electrostatic chuck or the like.

Then, on the XY stage, the single crystal member 10 is moved in the X-direction and the Y-direction, whereby the condensing lens 15 and the single crystal member 10 are moved relatively to each other in a direction parallel to the surface 10t of the single crystal member 10, on the side on which the condensing lens 15 is arranged, and meanwhile, the laser beams B are irradiated thereonto. In such a way, a large number of the cracks 12c are formed by the laser beams B condensed in the inside of the single crystal member 10. An aggregate of crack portions 12p having the cracks 12c is the modified layer 12 mentioned above. As a result that this modified layer 12 is formed, the internal modified layer-forming single crystal member 11 is manufactured. This internal modified layer-forming single crystal member 11 includes: the modified layer 12 formed in the inside of the single crystal member; a single crystal layer 10u on an upper side (that is, an irradiated side by the laser beams B); and a single crystal portion 10d on a lower side of the modified layer 12. The single crystal layer 10u and the single crystal portion 10d are formed in such a manner that the single crystal member 10 is divided by the modified layer 12.

Note that, in order to suppress a moving speed of the stage, the following may be used in combination, which is to scan the laser beams in an irradiation area of the condensing lens 15 by using a laser beam deflector such as a Galvano mirror and a polygon mirror. Moreover, such a procedure as below may also be adopted. That is to say, after the formation of the modified layer 12 by performing the internal irradiation as described above is ended, a focal point of the laser beams B is focused on such an irradiated-side surface 10t of the single crystal member 10, that is, on the surface 10t of the single crystal layer 10u, a mark indicating an irradiated region is put thereon, thereafter, the single crystal member 10 is cut (subjected to cleavage) while taking this mark as a reference, then a peripheral edge portion of the modified layer 12 is exposed as described later, and then exfoliation of the single crystal layer 10u may be performed.

In the modified layer 12 formed by the irradiation as described above, as shown in FIG. 4, the large number of cracks 12c parallel to an irradiation axis BC of the laser beams B are formed. It is preferable to set a dimension, density and the like of the cracks 12c, which are to be formed, in consideration of a material of the single crystal member 10 from a viewpoint of making it easy to exfoliate the single crystal layer 10u from the modified layer 12.

Note that, in order to confirm the cracks 12c, the internal modified layer-forming single crystal member 11 is subjected to the cleavage so that a processed region by the laser beams B, that is, the modified layer 12 can be traversed, and cleavage planes (for example, 14a to 14d in FIG. 3 and FIG. 5) are observed by a scanning electron microscope or a confocal microscope, whereby the cracks 12c may be confirmed. However, alternatively, with regard to a single crystal member (for example, a silicon wafer) of the same material, an inside thereof is subjected to a linear process under the same irradiation condition, for example, in a state where movement of the Y stage is set at an interval of 6 to 50 μm, then the single crystal member concerned is subjected to the cleavage in a form of traversing the same, and cleavage planes are observed, whereby cracks may be confirmed with ease.

(Exfoliation process)

Thereafter, the exfoliation between the modified layer 12 and the single crystal layer 10u is performed. In this embodiment, first, the modified layer 12 is exposed to the sidewall of the internal modified layer-forming single crystal member 11. In order to expose the modified layer 12, for example, the single crystal member 10 is subjected to the cleavage along predetermined crystal planes of the single crystal portion 10d and the single crystal layer 10u. As a result, as shown in FIG. 5, one with a structure in which the modified layer 12 is sandwiched between the single crystal layer 10u and the single crystal portion 10d is obtained. Note that the surface 10t of the single crystal layer 10u is a surface on the irradiated side of the laser beams B.

In the case where the modified layer 12 is already exposed, and in the case where a distance between the peripheral edge of the modified layer 12 and the sidewall of the internal modified layer-forming single crystal member 11 is sufficiently short, it is possible to omit this work of exposing the modified layer 12.

Thereafter, as shown in FIG. 6, metal-made substrates 28u and 28d are adhered onto upper and lower surfaces of the internal modified layer-forming single crystal member 11, respectively. That is to say, the metal-made substrate 28u is adhered onto the surface 10t of the single crystal layer 10u by an adhesive 34u, and the metal-made substrate 28d is adhered onto the surface 10b of the single crystal portion 10d by an adhesive 34d. Oxidation layers 29u and 29d are formed on surfaces of the metal-made substrates 28u and 28d, respectively. In this embodiment, the oxidation layer 29u is adhered onto the surface 10t, and the oxidation layer 29d is adhered onto the surface 10b. As the metal-made substrates 28u and 28d, for example, SUS-made exfoliation accessory plates are used. As such pieces of the adhesive, an adhesive is used, which is to be used in a usual semiconductor manufacturing process, and is to be used as a so-called wax for fixing a commercially available silicon ingot. Adhesive force of this adhesive is lowered when one having the adhesive adhered thereonto is immersed into water, and accordingly, the adhesive and an adhered object (single crystal layer 10u) can be separated from each other with ease.

In this adhesion, first, the metal-made substrate 28u is pasted onto the surface 10t of the single crystal layer 10u by a temporary fixation-use adhesive, and is exfoliated from a back thereof and applied with force.

Adhesive strength of the temporary fixation-use adhesive just needs to be stronger than force necessary to perform the exfoliation on an interface 11u between the modified layer 12 and the single crystal layer 10u. The dimension and density of the cracks 12c, which are to be formed, may be adjusted in response to the adhesive strength of the temporary fixation-use adhesive.

As the temporary fixation-use adhesive, for example, there is used an adhesive composed of acrylic-based two-liquid monomer components which are cured by taking metal ions as a reaction initiator. In this case, if an uncured monomer and a cured reaction product are water-insoluble, then an exfoliation surface 10f (for example, an exfoliation surface of the silicon wafer) of the single crystal layer 10u, which is exposed in the event where the single crystal member is exfoliated in water, can be prevented from being contaminated.

A coating thickness of the temporary fixation-use adhesive before curing is preferably 0.1 to 1 mm, more preferably, 0.15 to 0.35 mm. In the case where the coating thickness of the temporary fixation-use adhesive is excessively large, it takes a long time to completely cure the temporary fixation-use adhesive, and in addition, a cohesive fracture of the temporary fixation-use adhesive becomes prone to occur at the time of cutting and dividing the single crystal member (silicon wafer). Meanwhile, in the case where the coating thickness is excessively small, it takes a long time to exfoliate the cut and divided single crystal member in water.

Control for the coating thickness of the temporary fixation-use adhesive may be performed by using a method of fixing the metal-made substrates 28u and 28d, which are adhered onto each other, at arbitrary heights; however, in a simple way, can be performed by using a shim plate.

In the case where a degree of parallelization between the metal-made substrate 28u and the metal-made substrate 28d is not sufficiently obtained in the event of the adhesion thereof, then a required degree of parallelization may be obtained by using one or more accessory plates.

Moreover, in the event of adhering the metal-made substrates 28u and 28d onto the upper and lower surfaces of the internal modified layer-forming single crystal member 11 by the temporary fixation-use adhesive, the metal-made substrates 28u and 28d may be adhered thereonto one by one, or may be adhered thereonto simultaneously.

In the case where the coating thickness is desired to be strictly controlled, preferably, after the metal-made substrate is adhered onto one of the surfaces and the adhesive is cured, the metal-made substrate is adhered onto the other surface. In the case where the metal-made substrates are adhered one by one as described above, the surface onto which the temporary fixation-use adhesive is coated may be the upper surface or lower surface of the internal modified layer-forming single crystal member 11. In that event, a resin film that does not contain metal ions may be used as a cover layer in order to suppress the adhesive from being attached onto and cured on a non-adhered surface of the single crystal member 10.

No problem occurs even if the metal-made substrates are subjected to machining such as punching for device fixation as long as the sufficient degree of parallelization and a sufficient degree of planarity are obtained. The metal-made substrates to be adhered onto the single crystal member are subjected to the exfoliation process in water, and accordingly, it is preferable that the metal-made layers be those, which form passivation layers, for the purpose of suppressing the contamination of the silicon wafer, and it is preferable that the oxidation layers (oxidation coating layers), which are to be formed, be thinner for the purpose of shortening a cycle time of such underwater exfoliation.

Since the single crystal member is subjected to the underwater exfoliation after such an internally processed silicon wafer is cut and divided, it is preferable to perform metal degreasing treatment, which is performed in usual, for the metal-made substrates before the adhesion.

In order to enhance the adhesive force between the temporary fixation-use adhesive and the metal-made substrates, preferably, the oxidation layers on the metal surfaces are removed by a mechanical or chemical method, and active metal surfaces are exposed, and in addition, a surface structure, which makes it easy to obtain the anchor effect, is adopted. The above-described chemical method specifically includes acid cleaning, degreasing treatment and the like, which use chemicals. As the above-described mechanical method, there are specifically mentioned sandblast, shotblasting and the like; however, a method of scratching the surface of each of the metal-made substrates by sand paper is simplest and easiest, and a grain size thereof is preferably #80 to 2000, more preferably, #150 to 800 in consideration of surface damage of each metal-made substrate.

After the adhesion of the metal-made substrates, as shown in FIG. 6, upward force Fu is applied to the metal-made substrate 28u, and downward force Fd is applied to the metal-made substrate 28d. Here, the exfoliation is more likely to occur at an interface 11u between the modified layer 12 and the single crystal layer 10u than at an interface 11d between the modified layer 12 and the single crystal portion 10d. Therefore, as shown in FIG. 7, the modified layer 12 and the single crystal layer 10u are exfoliated from each other at the interface 11u therebetween by the forces Fu and Fd. By this exfoliation, the thin single crystal substrate 10s formed by exfoliating the single crystal layer 10u from the modified layer 12 is obtained.

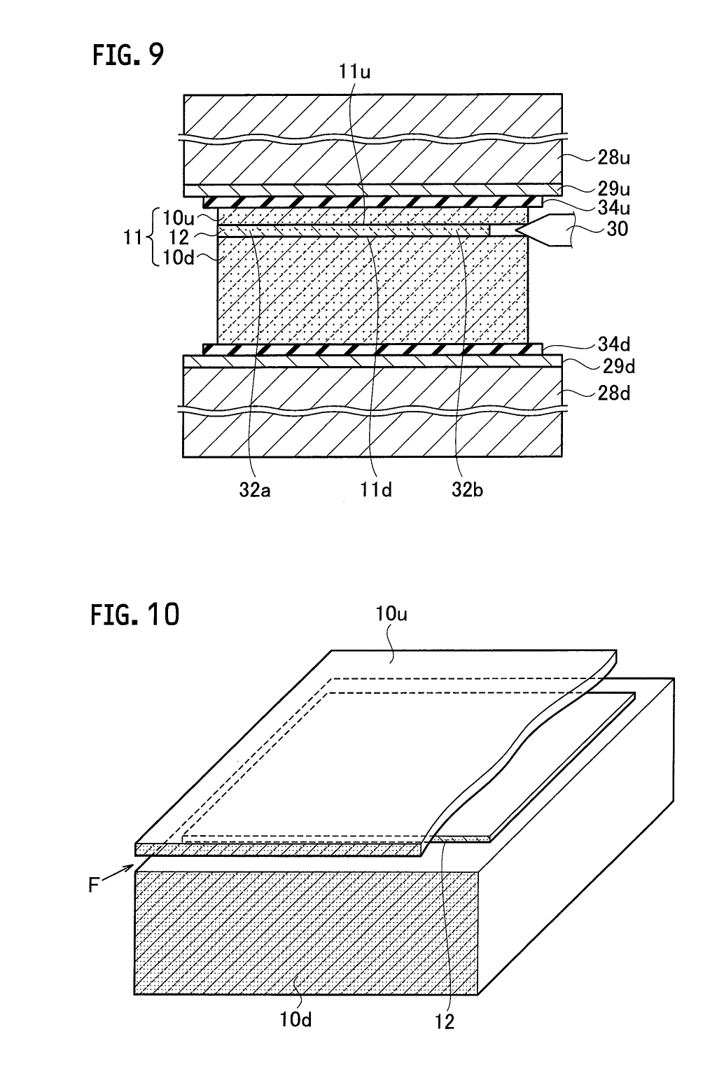

A method of applying the forces Fu and Fd is not particularly limited. For example, as shown in FIG. 8, the sidewall of the internal modified layer-forming single crystal member 11 is etched, whereby a groove 36 is formed on the modified layer 12, and as shown in FIG. 9, a wedge-like press-fitting member 30 (for example, a cutter blade) is press-fitted into this groove 36, whereby the forces Fu and Fd may be generated. Moreover, as shown in FIG. 10, force F is applied in a corner direction to the internal modified layer-forming single crystal member 11, whereby such an upward force component Fu and such a downward force component Fd may be generated.

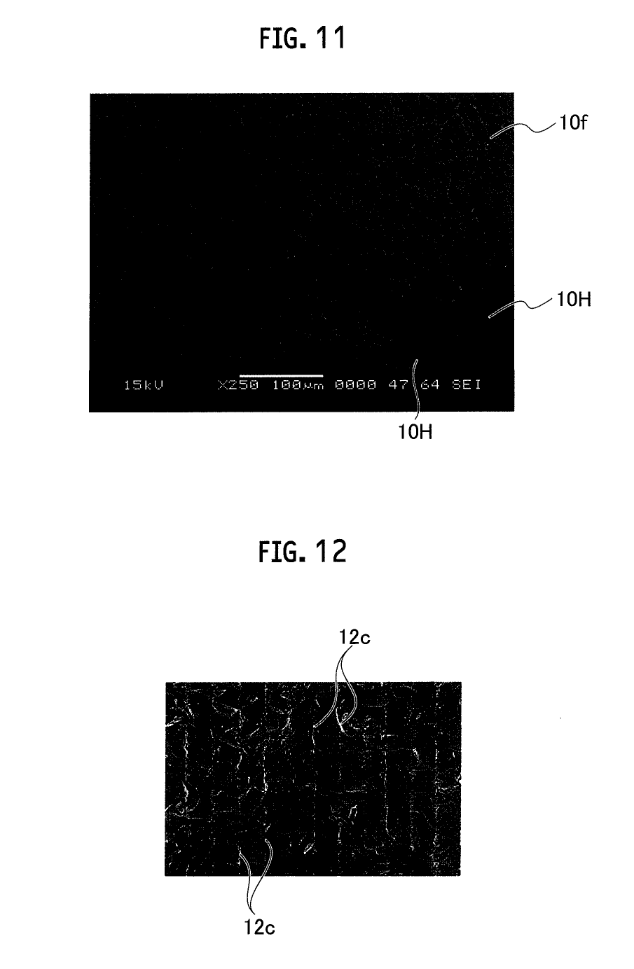

For example, as shown in FIG. 11, the exfoliation surface 10f of the single crystal substrate 10s, which is thus obtained, is a rough surface. Here, FIG. 11 is an optical microscope photograph of the exfoliation surface 10f of the single crystal substrate 10s. Note that, in FIG. 11, in order to make it easy to determine a photograph image, a surface 10H obtained by performing the cleavage for a crystal orientation plane is also partially generated and photographed.

As described above, in accordance with this embodiment, energy by the laser beams B can be concentrated on a thin thickness portion in the single crystal member 10 by the condensing lens 15 with a large NA. Hence, in the single crystal member 10, the internal modified layer-forming single crystal member 11, in which the modified layer (processed region) 12 with the small thickness T (length along the irradiation axis BC of the laser beams B) is formed, can be manufactured. Then, the single crystal layer 10u is exfoliated from the modified layer 12, whereby it is easy to manufacture the single crystal substrate 10s, which is thin. Moreover, the thin single crystal substrate 10s as described above can be manufactured with ease in a relatively short time. In addition, the thickness of the modified layer 12 is suppressed, whereby a large number of the single crystal substrates 10s is obtained from the single crystal member 10, and accordingly, a yield of the product can be enhanced.

Moreover, as the modified layer 12, the aggregate of the crack portions 12p parallel to the irradiation axis BC of the laser beams B is formed. In such a way, it is easy to exfoliate the modified layer 12 and the single crystal layer 10 from each other.

Moreover, in the event of exfoliating the single crystal layer 10 from the modified layer 12, the single crystal layer 10 is exfoliated, between the interfaces 11u and 11d, from the interface flu on the irradiated side of the laser beams, and the exfoliation surface 10f thus obtained is formed into the rough surface. Such an exfoliation surface 10f formed into the rough surface is used as an irradiated surface of sunlight, whereby light collection efficiency of the sunlight in the case where the exfoliation surface 10f is applied to a solar cell can be enhanced.

Moreover, in the process of forming the single crystal substrate 10s, the metal-made substrate 28u having the oxidation layer 29u on the surface thereof is adhered onto the surface of the single crystal layer 10u, and the single crystal layer 10u is exfoliated from the modified layer 12, whereby the single crystal substrate 10s is obtained. Hence, for the adhesion of the single crystal layer 10u with the metal-made substrate, the adhesive to be used in the usual semiconductor manufacturing process can be used, and a cyanoacrylate-based strong adhesive to be used in the event of adhering an acrylic plate is saved from being used. In addition, after the single crystal layer 10u is exfoliated, the single crystal layer 10u and the metal-made substrate 28u are immersed into water, whereby the adhesive force of the adhesive is lowered largely, and it becomes easy for the single crystal layer 10u to be exfoliated from the metal-made substrate 28u, and accordingly, the single crystal substrate 10s can be separated from the metal-made substrate 28u with ease.

Note that, in this embodiment, the description has been made on the following premise. Specifically, the metal-made substrates 28u and 28d are pasted onto the upper and lower surfaces of the internal modified layer-forming single crystal member 11, respectively, and the single crystal layer 10u is exfoliated by applying the forces to the metal-made substrates 28u and 28d, whereby the single crystal substrate 10s is formed. However, the single crystal layer 10s may be exfoliated by removing the modified layer 12 by etching.

Moreover, the single crystal member 10 is not limited to the silicon wafer, and as the single crystal member 10, there are applicable: an ingot of the silicon wafer; an ingot of single crystal sapphire, SiC or the like; a wafer cut out from this; an epitaxial wafer in which other crystal (GaN, GaAs, InP or the like) is grown on a surface of this; and the like. Moreover, a plane orientation of the single crystal member 10 is not limited to (100), and it is also possible to adopt other plane orientations.

### Test Example 1

The inventor of the present invention prepared a single crystal silicon wafer 10 (thickness: 625 μm), which was subjected to mirror polishing, as the single crystal member 10. Then, as Example 1, this silicon wafer 10 was mounted on the XY stage, and at a distance of 0.34 mm from the surface 10t of the silicon wafer 10 on the irradiated side of the laser beams, a second plano-convex lens 18 was arranged as the second lens 18. This second plano-convex lens 18 is a lens, in which a curvature radius is 7.8 mm, a thickness is 3.8 mm, and a refractive index is 1.58. Moreover, a first plano-convex lens 16 with an NA of 0.55 was arranged as the first lens 16.

Then, the laser beams B, in which a wavelength is 1064 nm, a repetition frequency is 100 kHz, a pulse width is 60 seconds, and an output is 1 W, were irradiated, and were passed through the first plano-convex lens 16 and the second plano-convex lens 18, whereby the modified layer 12 was formed in the inside of the silicon wafer 10. The depth D from the silicon wafer surface 10t to the processed region, that is, the depth D therefrom to the modified layer 12 was controlled by adjusting mutual positions of the first plano-convex lens 16 and the silicon wafer surface 10t. The thickness T of the modified layer 12 was controlled by adjusting mutual positions of the second plano-convex lens 18 and the silicon wafer surface 10t.

In the event of forming the modified layer 12, the laser beams B were irradiated while moving the silicon wafer 10 on the X stage at an equal speed by 15 mm, and subsequently, this irradiation was repeated after the silicon wafer 10 was fed on the Y stage by 1 μm, whereby internal irradiation of the laser beams was performed for an area with a size of 15 mm×15 mm. In such a way, the modified layer 12 was formed. As a result of this, the internal modified layer-forming single crystal member 11 was manufactured, which includes the single crystal layer 10u on the upper side (that is, the irradiated side of the laser beams B) of the modified layer 12, and includes the single crystal portion 10d on the lower side of the modified layer 12. In this embodiment, the single crystal layer 10u and the single crystal portion 10d are those formed in such a manner that the silicon wafer 10 is divided by the modified layer 12.

Thereafter, the silicon wafer 10 was subjected to the cleavage so as to traverse the modified layer 12, and the cleavage plane was observed by an optical microscope (scanning electronic microscope). An optical microscope photograph of the observed cleavage plane is shown in FIG. 12. It was confirmed that apparent cracks 12c were formed at an interval of 1 μm.

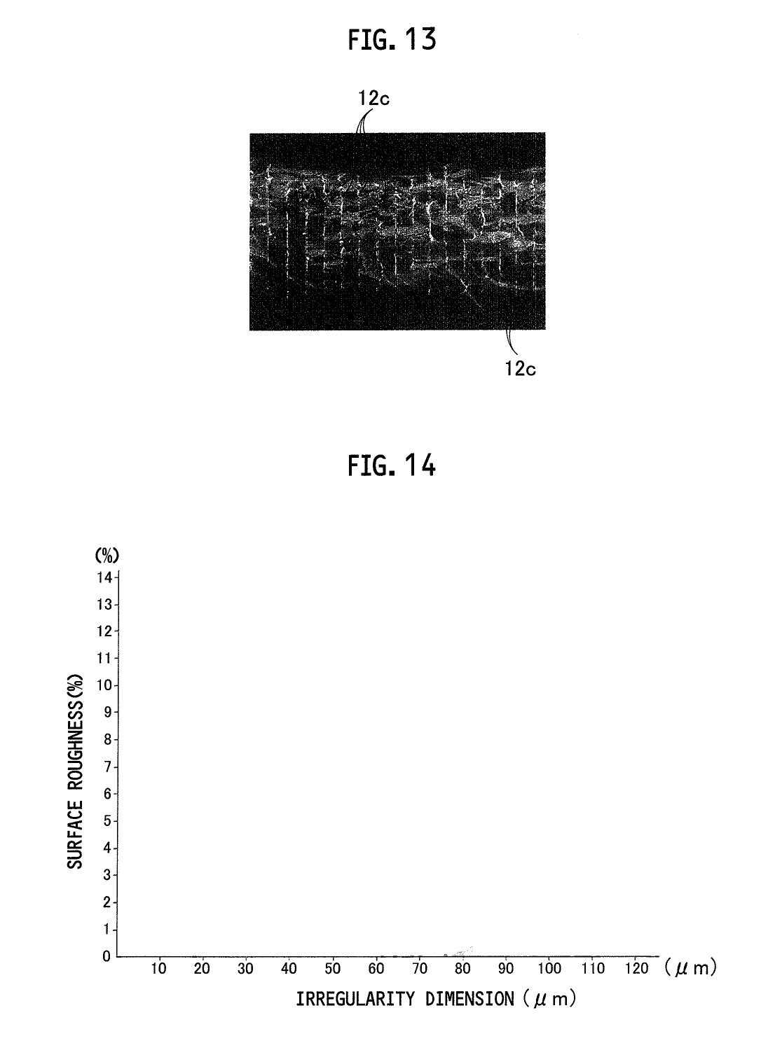

Moreover, as Example 2, the modified layer 12 was formed while changing, among the above-described implementation conditions, only a condition of feeding the silicon wafer 10 on the Y stage from 1 μm to 10 μm. Then, in a similar way, the silicon wafer 10 was subjected to the cleavage so as to traverse the modified layer 12, and the cleavage plane was observed by the optical microscope (scanning electronic microscope). An optical microscope photograph of the observed cleavage plane is shown in FIG. 13. It was confirmed that apparent cracks 12c were formed at an interval of 10 μm.

Furthermore, as Example 3, such a procedure was repeated, in which, after the laser beams were irradiated as in Example 2, the laser beams were irradiated onto the silicon wafer 10 while moving the silicon wafer 10 on the Y stage at an equal speed after the silicon wafer 10 was fed on the X stage by 10 μm. That is to say, the laser beams were irradiated in a grid manner. Then, in a similar way, the silicon wafer 10 was subjected to the cleavage so as to traverse the modified layer 12, and the cleavage plane was observed by the optical microscope (scanning electronic microscope). Cracks were formed more apparently and largely than in Example 2.

### Test Example 2

Moreover, the inventor of the present invention manufactured an internal modified layer-forming single crystal member 11, which was composed by forming the modified layer 12, under the implementation conditions of Example 1 by using a silicon wafer similar to the silicon wafer 10 used in Test example 1. Then, the single crystal layer 10u was exfoliated by using the metal-made substrates 28u and 28d, and the single crystal substrate 10s was obtained. When the exfoliation surface 10f of this single crystal substrate 10s was observed by a laser confocal microscope, then a measurement chart shown in FIG. 14 was obtained, and it was confirmed that irregularities with a particle diameter of 50 to 100 μm were formed on the exfoliation surface 10f. Here, in FIG. 14, an axis of abscissas represents an irregularity dimension (displayed by “μm”), and an axis of ordinates represents surface roughness (displayed by “%”).

### Test example 3

### Example 4

The inventor of the present invention prepared a single crystal silicon wafer 10 (thickness: 625 μm), in which both surfaces were subjected to the mirror polishing, as the single crystal member 10. Then, as Example 4, this silicon wafer 10 was mounted on the XY stage, pulse laser beams with a wavelength of 1064 nm were irradiated thereonto, and such a modified layer 12, which had a square shape with one side of 5 mm when viewed from the above, was formed. Then, this silicon wafer (internal modified layer-forming single crystal member) was subjected to the cleavage, whereby a cross section of the modified layer 12 was exposed, and this cross section was observed by the scanning electron microscope. The thickness T of the modified layer 12 was 30 μm.

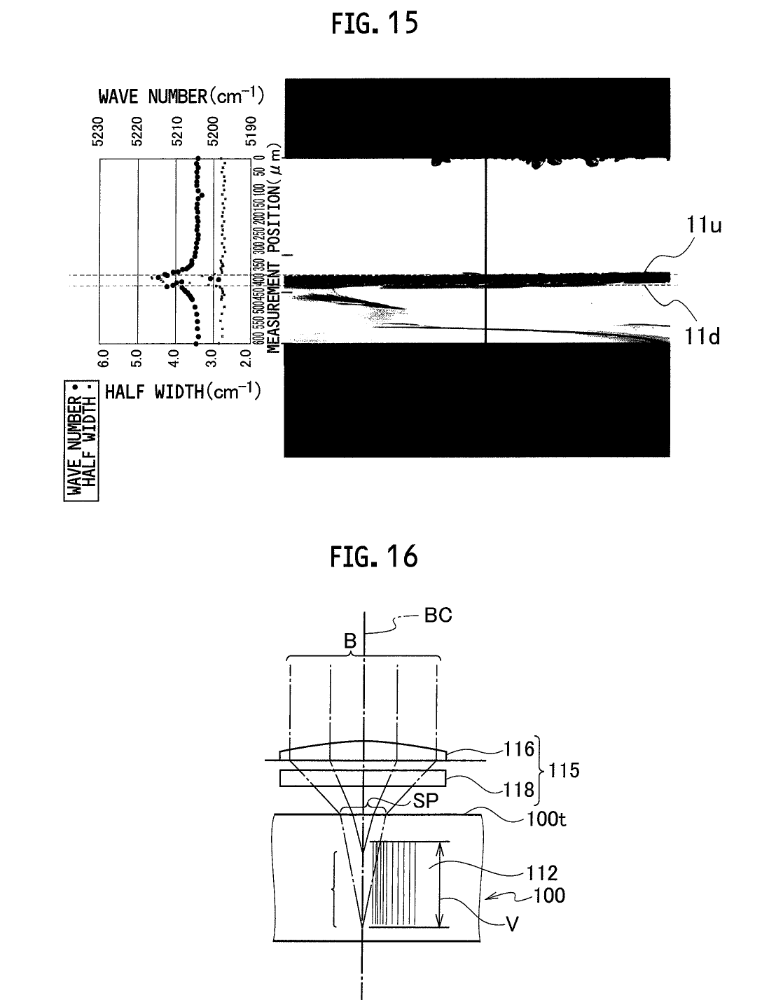

Subsequently, a Raman spectrum of this cross section was measured. A spectrum chart obtained by the measurement is shown in FIG. 15. A large shift of the spectrum on a high wave number side was observed in the vicinity of the interfaces 11 u and 11d, and it was confirmed that a large compressive stress occurred therein.

### Comparative Example

Moreover, by using a silicon wafer similar to the silicon wafer used in Example 4, the inventor of the present invention conducted a test of Comparative example in the following manner. FIG. 16 is a schematic bird's eye view explaining that laser beams are condensed in air by a laser condenser in this Comparative example. In comparison with Example 4, in Comparative example, a condensing lens 115 is arranged as the laser condenser instead of the condensing lens 15. This condensing lens 115 for use in this Comparative example is composed of: a first lens 116 as a plano-convex lens; and an aberration-increasing glass plate 118 arranged between the first lens 116 and a surface of a silicon wafer 100. This aberration-increasing glass plate 118 is arranged as described above, whereby such laser beams B, which form a laser spot SP on the surface of the silicon wafer 100 as an irradiation target, are refracted on such a silicon wafer surface 100t, then as laser beams, enter an inside of the silicon wafer, and form an image, which has predetermined depth position and width, in the event of forming a condensing point in the inside of the silicon wafer. That is to say, in the inside of the silicon wafer, a modified layer 112 (processed region) can be formed with a predetermined thickness V at a predetermined depth position. Here, the aberration is increased by the aberration-increasing glass plate 118, and accordingly, this predetermined thickness V becomes larger than the thickness T of the modified layer 12 in Example 4.

In this Comparative example, cover glass with a diameter of 0.15 mm was attached as the aberration-increasing glass plate 118 onto a microscope-use objective lens with an NA of 0.8 and a magnification of 100 times. Then, pulse laser beams with a wavelength of 1064 nm were irradiated onto the silicon wafer 100 at the same frequency and output as those in the case of Example 4, and the modified layer 112, which had a square shape with one side of 5 mm when viewed from the above, was formed. Then, this silicon wafer 100 was subjected to the cleavage, whereby a cross section of the modified layer 112 was exposed, and this cross section was observed by the scanning electron microscope. A thickness of this modified layer 112 was 80 to 100 μm.

Subsequently, when a Raman spectrum of this cross section was measured, it was confirmed that large stresses as in Example 4 were not present in the interfaces on the upper and lower sides of the modified layer 112.

Hence, in accordance with this Test example, in comparison with Comparative example, in Example 4, it is found out that, since the thickness of the modified layer 112 processed and formed by the laser beams in the inside of the silicon wafer (the inside of the single crystal member) is small, an energy loss involved in the processing can be reduced.

Moreover, in Example 4, the large compressive stress is present in the vicinity of the interfaces 11u and 11d. Also by the presence of this stress, it is easier to exfoliate the single crystal layer from the modified layer in Example 4 than in Comparative example.

### Second Embodiment

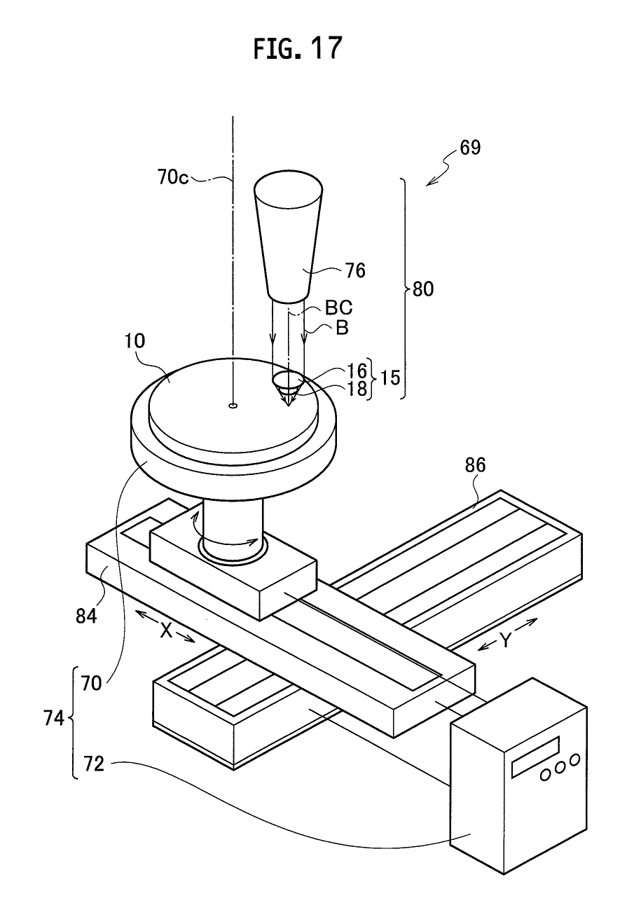

Next, a description is made of a second embodiment. FIG. 17 is a schematic bird's eye view of a single crystal member inside processing apparatus for use in the event of explaining a single crystal substrate manufacturing method according to this embodiment and an internal modified layer-forming single crystal member according thereto.

A single crystal member inside processing apparatus 69 to be used in this embodiment includes a substrate rotator 74 having: a rotating stage 70 that holds a single crystal member 10 mounted on an upper surface side thereof; and a rotating stage control unit 72 that controls the number of revolutions of the rotating stage 70. Then, the single crystal member inside processing apparatus 69 includes an irradiation device 80 having: a laser light source 76; the condensing lens 15; and a focal point position adjusting tool (not shown) that adjusts a distance from the condensing lens 15 to the rotating stage 70. Moreover, the single crystal member inside processing apparatus 69 includes an X-direction moving stage 84 and a Y-direction moving stage 86, which move the rotating stage 70 and the condensing lens 15 relatively to each other between a rotation axis 70c of the rotating stage 70 and an outer circumference of the rotating stage 70.

In this embodiment, this single crystal member inside processing apparatus 69 is used, the single crystal member 10 is mounted on the rotating stage 70, and the laser beams B are irradiated onto the single crystal member 10 while rotating the single crystal member 10 at an equal speed by the rotating stage 70. Subsequently, the rotating stage 70 is moved by the X-direction moving stage 84 and the Y-direction moving stage 86, whereby an irradiation position of the laser beams B is fed at a predetermined interval (1 μm, 5 μm, 10 μm or the like) in a radius direction of the rotating stage 70, and thereafter, irradiation of the laser beams B is repeated. In such a way, a two-dimensional modified layer can be formed in an inside of the single crystal member 10.

In this embodiment, such a moving direction of the condensing point of the laser beams B becomes circular, and accordingly, the cracks generated by the condensation of the laser beams are located on circles concerned. Then, the irradiation is repeated after the irradiation position of the laser beams B is fed in the radius direction of the rotating stage 70 at a predetermined interval, whereby the cracks can be located concentrically. Then, the internal modified layer-forming single crystal member as described above is manufactured, and the exfoliation is performed in a similar way to the first embodiment, whereby a single crystal substrate can be manufactured.

Note that, for example, a plurality of square single crystal members may be arranged at an interval on the rotating stage 70 symmetrically with respect to the rotation axis 70c. In such a way, the cracks by the condensation of the laser beams B can be arranged on circular arcs which partially compose circles.

### Industrial Applicability

By the present invention, the thin single crystal substrate can be formed efficiently. Accordingly, if the single crystal substrate cut out thinly is a Si substrate, then the single crystal substrate is applicable to a solar cell, moreover, if the single crystal substrate is a sapphire substrate of a GaN-based semiconductor device or the like, then the single crystal substrate is applicable to a light emitting diode, a laser diode or the like, and further, if the single crystal substrate is SiC or the like, then the single crystal substrate is applicable to a SiC-based power device or the like. As described above, the present invention is applicable to wide-range fields such as the transparent electronics field, the illumination field, and the hybrid/electric vehicle field.

### Reference Symbol List

10 SINGLE CRYSTAL MEMBER, SILICON WAFER
10u SINGLE CRYSTAL LAYER
10d SINGLE CRYSTAL PORTION
10s SINGLE CRYSTAL SUBSTRATE
10t SURFACE
10b SURFACE
10f EXFOLIATION SURFACE
11 INTERNAL MODIFIED LAYER-FORMING SINGLE CRYSTAL MEMBER
11u INTERFACE
12 MODIFIED LAYER
12p CRACK PORTION
15 CONDENSING LENS (LASER CONDENSER)
28u METAL-MADE SUBSTRATE
29u OXIDATION LAYER
B LASER BEAM
BC IRRADIATION AXIS
E OUTER CIRCUMFERENTIAL PORTION
M CENTER PORTION
L1 DISTANCE
L2 DISTANCE
T THICKNESS

1. A manufacturing method of a single crystal substrate, comprising the steps of:
arranging a laser condenser contactlessly on a single crystal member, the laser condenser emitting laser beams and correcting aberration caused by a refractive index of the single crystal member;
by the laser condenser, irradiating the laser beams onto a surface of the single crystal member, and condensing the laser beams into an inside of the single crystal member;
moving the laser condenser and the single crystal member relatively to each other, and forming a two-dimensional modified layer in the inside of the single crystal member; and
exfoliating a single crystal layer from the modified layer, the single crystal layer being formed by being divided by the modified layer, thereby forming a single crystal substrate.

2. The manufacturing method of a single crystal substrate according to claim 1, wherein an aggregate of crack portions parallel to an irradiation axis of the laser beams is formed as the modified layer.

3. The manufacturing method of a single crystal substrate according to claim 2, wherein an exfoliation surface formed by the exfoliation is a rough surface.

4. The manufacturing method of a single crystal substrate according to claim 1, wherein, in the step of forming a single crystal substrate, the single crystal layer is exfoliated from an interface on a side onto which the laser beams are irradiated, the side belonging to both surface sides of the modified layer.

5. The manufacturing method of a single crystal substrate according to claim 1, wherein, in the step of forming a single crystal substrate, a metal-made substrate having an oxidation layer on a surface thereof is adhered onto a surface of the single crystal layer, and the single crystal layer is exfoliated from the modified layer.

6. The manufacturing method of a single crystal substrate according to claim 1, wherein correction is made so that, in an event where light rays are condensed in air, light rays which have reached an outer circumferential portion of the laser condenser can be condensed on the laser condenser side more than light beams which have reached a center portion of the laser condenser are.

7. The manufacturing method of a single crystal substrate according to claim 6, wherein the laser condenser includes:
a first lens that condenses the light rays in the air; and
a second lens arranged between the first lens and the single crystal member.

8. The manufacturing method of a single crystal substrate according to claim 7, wherein a distance to the modified layer from the surface of the single crystal member on a side onto which the laser beams are irradiated is adjusted by a distance between the first lens and the surface of the single crystal member.

9. The manufacturing method of a single crystal substrate according to claim 8, wherein a thickness of the modified layer is adjusted by a distance between the second lens and the surface of the single crystal member on the side onto which the laser beams are irradiated.

10. A manufacturing method of an internal modified layer-forming single crystal member for forming a modified layer in an inside of a single crystal member by irradiating laser beams onto the single crystal member from a surface of the single crystal member and condensing the laser beams in an inside of the single crystal member, and for exfoliating the single crystal substrate from the modified layer, the manufacturing method comprising the steps of:
arranging a laser condenser contactlessly on the single crystal member, the laser condenser emitting the laser beams and correcting aberration caused by a refractive index of the single crystal member;
by the laser condenser, irradiating the laser beams onto the surface of the single crystal member, and condensing the laser beams into the inside of the single crystal member; and
moving the laser condenser and the single crystal member relatively to each other, and forming a two-dimensional modified layer in the inside of the single crystal member.
